(19) United States
(12) Patent Application Publication
(10) Pub. No.: US 2005/0202650 A1
(43) Pub. Date: Sep. 15, 2005

(54) Method of dividing a wafer which has a low-k film formed on dicing lines

(76) Inventors: Yoshihisa Imori, Yokohama-shi (JP); Masahiko Hori, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/072,318

(22) Filed: Mar. 7, 2005

(30) Foreign Application Priority Data
Mar. 8, 2004 (JP) 2004-064521

(51) Int. Cl. H01L 21/301

(52) U.S. Cl. 438/462

(57) ABSTRACT

Semiconductor elements are formed in a wafer. At the upper layer of the wafer, a multilayer film including a low-relative-permittivity insulating film is formed. Thereafter, on a dicing line of the multilayer film, a metal layer functioning as at least an alignment mark and a test pad is formed. Next, laser is irradiated onto a region covering the alignment mark and test pad on the dicing line. Then, mechanical dicing is performed on at least one of the alignment mark and test pad on the dicing line in such a manner that the dicing is narrower in width than the laser-irradiated region, thereby segmenting the semiconductor wafer, which forms semiconductor chips.

### CROSS-REFERENCE TO RELATED APPLICATIONS

This application is based upon and claims the benefit of priority from prior Japanese Patent Application No. 2004-064521, filed Mar. 8, 2004, the entire contents of which are incorporated herein by reference.

### BACKGROUND OF THE INVENTION

1. Field of the Invention

This invention relates to a semiconductor device manufacturing method, and more particularly a method of dividing a wafer which has, for example, a multilayer film including a low-relative-permittivity insulating film as an interlayer insulating film and which further has a metal layer, including alignment marks and test pads, provided on the dicing lines at the multilayer film.

2. Description of the Related Art

With the recent miniaturization of LSIs, a wiring delay problem has been coming to the surface. The miniaturization of transistors enables speeding up to be expected from the scaling effect. While a decrease in the wiring length produces the effect of reducing the delay, a decrease in the width of each wiring line and a decrease in the spacing between wiring lines cause the wiring delay (RC delay) to increase. The delay is determined by the parasitic resistance R and parasitic capacitance C of a wiring line. As wiring lines are miniaturized, the values of R and C both basically become larger.

The parasitic resistance R of a wiring line can be reduced by using a low-resistance wiring material. The lower the effective permittivity keff of an interlayer insulating film filling the spacing between wiring lines, the smaller the parasitic capacitance C. Therefore, the delay can be reduced. Since a decrease in the value of the relative permittivity k of the interlayer insulating film wouldn't require the parasitic capacitance to increase much, a low-relative-permittivity interlayer insulating film called Low-k is desired.

The low-relative-permittivity insulating film generally has a porous structure. Therefore, it has the problems of having a low mechanical strength and being much lower in adhesiveness than a silicon oxide film widely used.

The properties of the low-relative-permittivity insulating film cause a serious problem when a wafer is segmented into chip products. Specifically, in the film forming process, the insulating film is also formed on the dicing lines of the wafer. When an ordinary segmentation process is carried out by blade dicing, chipping and the peeling of the insulating film are liable to take place.

To overcome this problem, wafer dicing techniques using laser have been proposed (refer to, e.g., Jpn. Pat. Appln. KOKAI Publication No. 2002-192367). Mechanical cutting with a blade causes mechanical damage directly to the insulating film, whereas ablation processing by laser causes less mechanical damage because vaporizing the insulating film instantaneously.

However, in the ablation processing, depending on the difference in reflection property between objects to be processed, processing conditions have to be changed between a case where only a multilayer film is severed and a case where the test pads and alignment marks placed on the dicing lines are severed. While one of them can be optimized, both of them cannot be processed under optimum conditions. For this reason, when a multilayer film is severed under optimum conditions, the metal layers, including the test pads and alignment marks, cannot be severed easily, with the result that the peeling of the multilayer film occurs under the condition that cutting is done by only laser.

Therefore, it has been necessary to place design restraints on the arrangement of the test pads and alignment marks on the dicing lines and slow down the laser scanning speed to realize less damage processing conditions. As a result, the dicing region has become larger, reducing the chip yield. Moreover, the decrease of the laser scanning speed has lowered the operating efficiency.

### BRIEF SUMMARY OF THE INVENTION

According to an aspect of the present invention, there is provided a semiconductor device manufacturing method comprising: forming semiconductor elements in a semiconductor wafer; forming a multilayer film including a low-relative-permittivity insulating film, at the upper layer of the semiconductor wafer; forming a metal layer functioning as at least an alignment mark and a test pad, on a dicing line of the multilayer film; irradiating laser onto a region covering the alignment mark and test pad on the dicing line; and performing mechanical dicing on at least one of the alignment mark and test pad on the dicing line in such a manner that the dicing is narrower in width than the laser-irradiated region, thereby segmenting the semiconductor wafer to form semiconductor chips.

### BRIEF DESCRIPTION OF THE SEVERAL VIEWS OF THE DRAWING

FIG. 1A is an enlarged plan view of a dicing line and its vicinity in a first manufacturing step to help explain a semiconductor device manufacturing method according to a first embodiment of the present invention;

FIG. 1B is a sectional view taken along line 1B-1B of FIG. 1A in the first manufacturing step to help explain the semiconductor device manufacturing method of the first embodiment;

FIG. 2A is an enlarged plan view of a dicing line and its vicinity in a second manufacturing step to help explain the semiconductor device manufacturing method of the first embodiment;

FIG. 2B is a sectional view taken along line 2B-2B of FIG. 2A in the second manufacturing step to help explain the semiconductor device manufacturing method of the first embodiment;

FIG. 3A is an enlarged plan view of a dicing line and its vicinity in a third manufacturing step to help explain the semiconductor device manufacturing method of the first embodiment;

FIG. 3B is a sectional view taken along line 3B-3B of FIG. 3A in the third manufacturing step to help explain the semiconductor device manufacturing method of the first embodiment;

FIG. 4A is an enlarged plan view of a dicing line and its vicinity to help explain a semiconductor device manufacturing method according to a second embodiment of the present invention;

FIG. 4B is a sectional view taken along line 4B-4B of FIG. 4A to help explain the semiconductor device manufacturing method of the second embodiment;

FIG. 5A is an enlarged plan view of a dicing line and its vicinity to help explain a semiconductor device manufacturing method according to a third embodiment of the present invention;

FIG. 5B is a sectional view taken along line 5B-5B of FIG. 5A to help explain the semiconductor device manufacturing method of the third embodiment;

FIG. 6 is a characteristic diagram showing the relationship between the laser irradiation position and the output;

FIG. 7 is a characteristic diagram showing the relationship between the laser irradiation position and the output to help explain modification 1 of the semiconductor device manufacturing method according to the first and third embodiments; and

FIG. 8 is a characteristic diagram showing the relationship between the laser irradiation position and the output to help explain modification 2 of the semiconductor device manufacturing method according to the first and third embodiments.

### DETAILED DESCRIPTION OF THE INVENTION

### First Embodiment

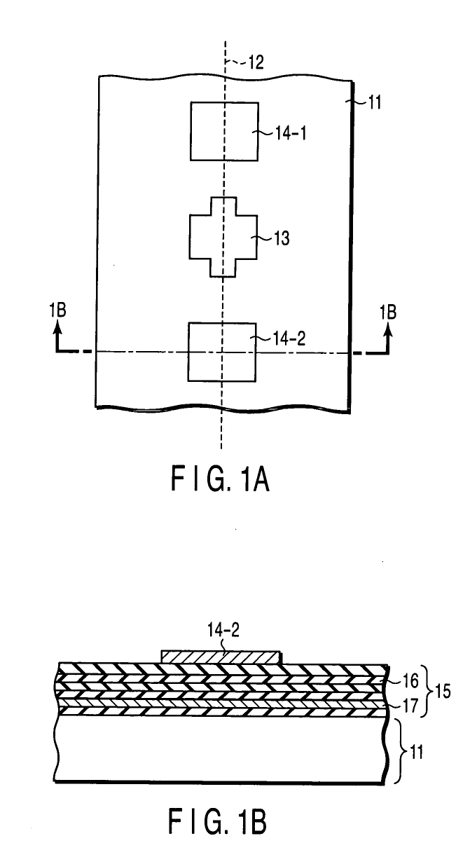

FIGS. 1A, 1B, FIGS. 2A, 2B, and FIGS. 3A, 3B are diagrams to help explain a semiconductor device manufacturing method according to a first embodiment of the present invention. These figures show the wafer dividing steps sequentially.

First, various semiconductor elements are formed in a semiconductor waver by known techniques.

Next, as shown in FIGS. 1A and 1B, after a multilayer film 15 with a stacked structure including a low-relative-permittivity insulating film 16 and a wiring layer 17 is formed on the semiconductor wafer 11, a metal layer is formed on the multilayer film 15, which is then patterned to form at least either an alignment mark 13 or test pads 14-1, 14-2. The alignment mark 13 and test pads 14-1, 14-2 are arranged on a dicing line 12 of the wafer 11.

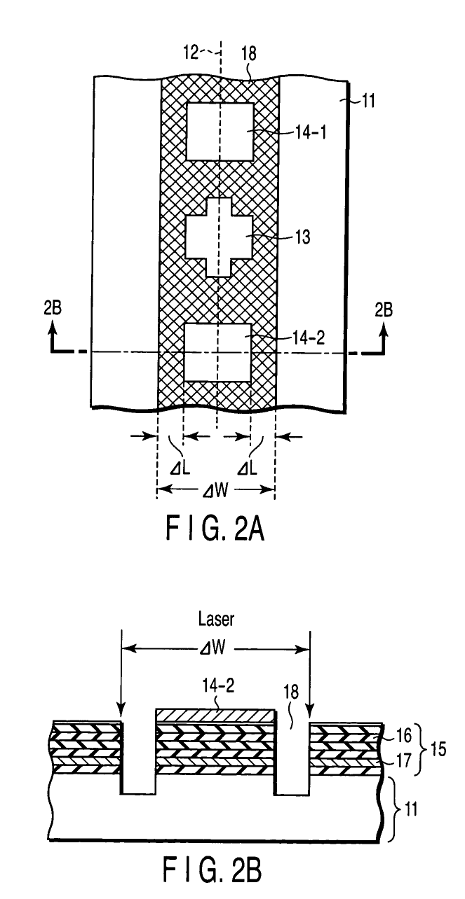

Thereafter, the wafer 11 is mounted on a laser dicing tape and then set on a laser processing machine. Then, after positioning is performed using the alignment mark 13 and the dicing line 12 is recognized, laser is irradiated with a width of ΔW that covers the whole of the alignment mark 13 and test pads 14-1, 14-2 arranged on the dicing line 12 as shown in FIGS. 2A and 2B. In this way, the wafer is scanned with the laser. A YAG-THG laser, a YVO4 laser, a CO₂ laser, and the like may be used as the laser irradiation unit. In this case, laser is irradiated onto a region at least 3 μm (ΔL≧3 μm) wider than either end of the alignment mark 13 and test pads 14-1, 14-2.

Depending slightly on the laser irradiation conditions and the material of the irradiated region, a margin of at least 3 μm is given between the laser irradiation end and the edge of the alignment mark 13 or test pads 14-1, 14-2, which prevents the multilayer film 15 from peeling off. Giving a margin of 5 μm prevents the peeling of the multilayer film 15 more effectively.

The wavelength, frequency, output, and scanning speed of the laser and others are set to the optimum values that enable the multilayer film 15 to change its nature, melt, or evaporate to expose at least the wafer surface. For example, the applicable frequency is in the range of 50 KHz to 200 KHz, the frequency is in the range of 266 nm to 1064 nm (more preferably 266 nm to 355 nm), and the average output is in the range of 0.5 W to 3.0 W. The laser scanning speed is effective in the range of 10 mm/sec to 300 mm/sec. When laser is irradiated in pulse form, damage to the irradiated region can be reduced. The pulse width is in the range of 10 nsec to 300 nsec.

When the output of the laser (power density) is small and the scanning speed is slow, the cut surface melts and recrystallizes. When the output of the laser beam is large and the scanning speed is fast, the cut surface evaporates. When the wavelength of the laser beam is short, the beam cuts well, causing less damage. The conditions, including the laser wavelength, average output, and scanning speed, are set according to the size, thickness, and the like of a semiconductor wafer or chip, which enables the surface state to be optimized.

As a result, the multilayer film 15 excluding its part below the metal layer, including the alignment mark 13 and test pads 14-1, 14-2, in the laser irradiation region is removed or changes its nature, which forms a region 18 solidified after being melted by laser irradiation.

FIG. 2B shows an example of setting a depth which enables the multilayer film 15 to be severed completely and a part of the surface of the wafer 11 to be melted. With this depth, the region 18 solidified after melting is formed on the sidewall of the multilayer film 15. At the same time, the wafer 11 (silicon) is melted and silicon adheres to the multilayer film 15.

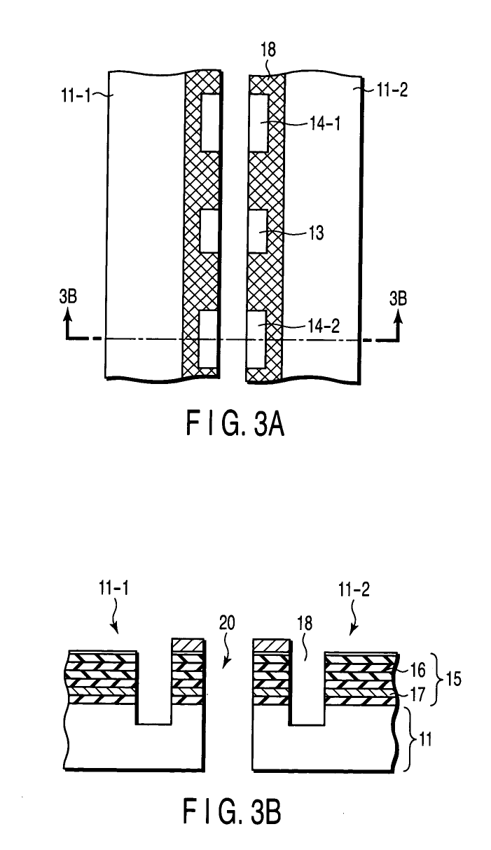

Thereafter, as shown in FIGS. 3A and 3B, blade dicing is performed along the dicing line 12, segmenting the wafer 11, which forms semiconductor chips 11-1, 11-2. In each of the chips 11-1, 11-2, the region 18 solidified after being melted by laser irradiation has been formed at the upper end of the sidewall of the multilayer film 15. At the end of each of the chips 11-1, 11-2, the alignment mark 13, test pads 14-1, 14-2, multilayer film 15, and others remain intact.

With the above configuration and manufacturing method, after laser is irradiated widely so as to cover the alignment mark 13 and test pads 14-1, 14-2, thereby processing the multilayer film 15, the wafer is divided into individual chips 11-1, 11-2 by blade dicing. This prevents the chipping or peeling of the multilayer film 15, particularly the peeling of the low-relative-permittivity insulating film 16. Since there is no need to arrange the alignment mark 13, test pads 14-1, 14-2, and others on a line different from the laser irradiation region 18, there is no restrictions on design, enabling the dicing lines to be made narrower, which increases the chip yield from a single wafer 11. Moreover, there is no need to slow down the laser scanning speed, which improves the operating efficiency.

As described above, with the semiconductor device manufacturing method of the first embodiment, when a low-relative-permittivity insulating film or a multilayer film including this insulating film is used, blade dicing is performed by laser irradiation in a state where chipping and the peeling of a film are suppressed, which prevents chipping and the peeling of a low-relative permittivity insulating film.

While in FIG. 3A, the alignment mark 13, test pads 14-1, 14-2, multilayer film 15, and others are allowed to remain intact at the ends of the chips 11-1, 11-2, these may be removed or absent, depending on the blade dicing condition, and a step portion between the laser irradiation region 18 and the blade dicing region 20 may be formed at the sidewall of each of the chips 11-1, 11-2.

As described above, even when the step portion between the laser irradiation region 18 and the blade dicing region 20 is formed at the sidewall of each of the chips 11-1, 11-2, chipping and the peeling of the multilayer film 15 is, of course, prevented.

### Second Embodiment

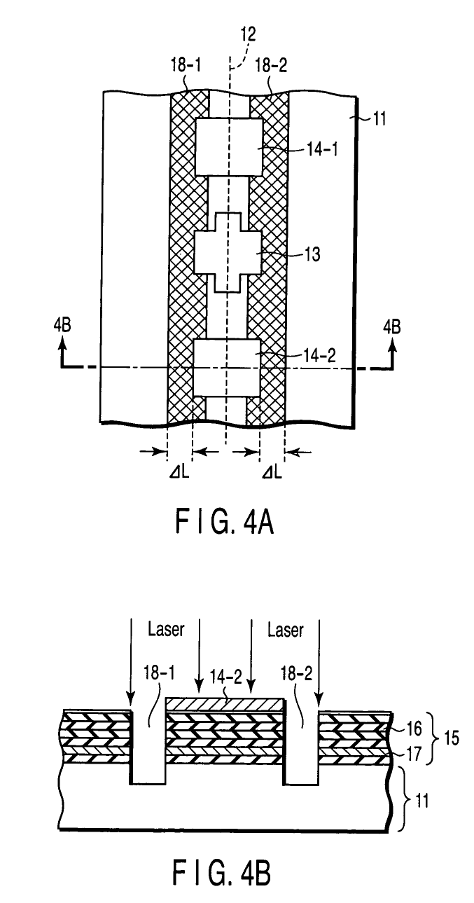

FIGS. 4A and 4B are diagrams to help explain a semiconductor device manufacturing method according to a second embodiment of the present invention. These figures show the wafer dividing steps. The steps of FIGS. 4A and 4B correspond to the steps of FIGS. 2A and 2B in the first embodiment, respectively.

As shown in FIG. 4A, at both ends of the alignment mark 13 and test pads 14-1, 14-2 provided on the dicing line 12, two laser irradiation regions 18-1, 18-2 are formed so as to cover either end. At this time, the width (ΔL) from the edge of the alignment mark 13 and test pads 14-1, 14-2 to the edge of the laser irradiation regions 18-1, 18-2 is set to 3 μm, more preferably 5 μm or more as in the first embodiment.

The second embodiment shows an example of setting a depth that enables the multilayer film 15 to be severed completely and a part of the surface of the wafer 11 to be melted by laser as shown in FIG. 4B. With this depth, a region solidified after melting is formed on the sidewall of the multilayer film 15. At the same time, the wafer 11 (silicon) is melted and silicon adheres to the multilayer film 15.

The subsequent steps are the same as in the first embodiment. Blade dicing is performed along the dicing line 12, thereby segmenting the wafer 11, which forms chips 11-1, 11-2.

As described above, even when laser is irradiated to the wafer excluding the region on which blade dicing is to be performed, chipping and the peeling of the multilayer film 15 can be prevented in the laser irradiation regions 18-1, 18-2. Therefore, the second embodiment produces practically the same effect as the first embodiment.

### Third Embodiment

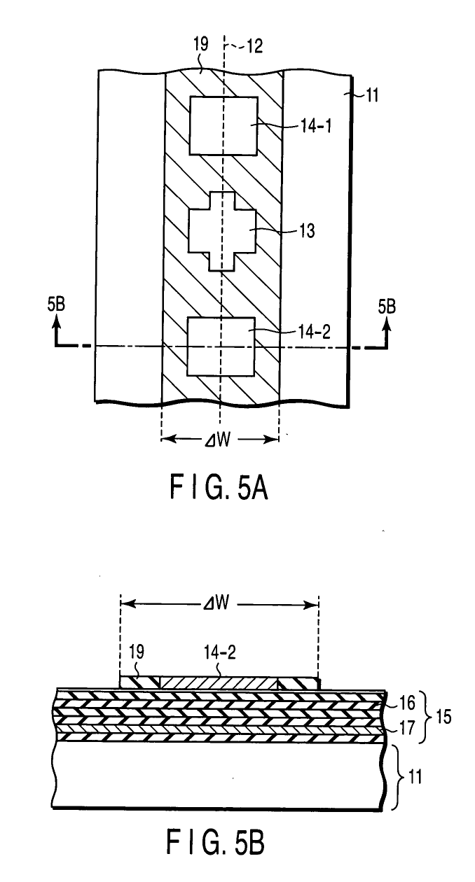

FIGS. 5A and 5B are diagrams to help explain a semiconductor device manufacturing method according to a third embodiment of the present invention. FIG. 5A is an enlarged plan view of a dicing line and its vicinity and FIG. 5B is a sectional view taken along line 5B-5B of FIG. 5A.

As shown in FIG. 5A, an alignment mark 13 and test pads 14-1, 14-2 made of metal layers are provided on a dicing line 12 of a wafer 11 and a laser absorbing member layer 19 is provided in a region to which laser is irradiated. As in the first and second embodiments, on the wafer 11, a multilayer film 15 is provided as shown in FIG. 5B. On the multilayer film 15, the alignment mark 13 and test pads 14-1, 14-2 are formed. The multilayer film 15 has a stacked structure including a low-relative-permittivity insulating film 16 and a wiring layer 17. In the laser irradiation regions on the periphery of the alignment mark 13 and test pads 14-1, 14-2 on the multilayer film 15, the laser absorbing member layer 19 is provided.

For example, the laser absorbing layer is formed as follows. First, semiconductor elements are formed in the wafer 11. On the wafer 11, a multilayer film 15 including a low-relative-permittivity insulating film 16 is formed. Then, a metal layer is formed on the multilayer film 15. The metal layer is patterned, thereby forming an alignment mark 13 and test pads 14-1, 14-2, followed by the formation of a laser absorbing member layer 19 on the whole surface. Thereafter, the laser absorbing member 19 excluding the laser irradiation regions is removed by etching or the like.

As described above, providing the laser absorbing member layer 19 in the laser irradiation regions makes it easier for laser to be absorbed at the surface of the multilayer film 15, which enables the laser process to be carried out effectively under the condition of low output.

While in the third embodiment, the laser absorbing member layer 19 has been provided only in the laser irradiation regions, it may be formed by using a material which is formed in an element region of the wafer 11 (chip) and functions as a protective film.

### Modification

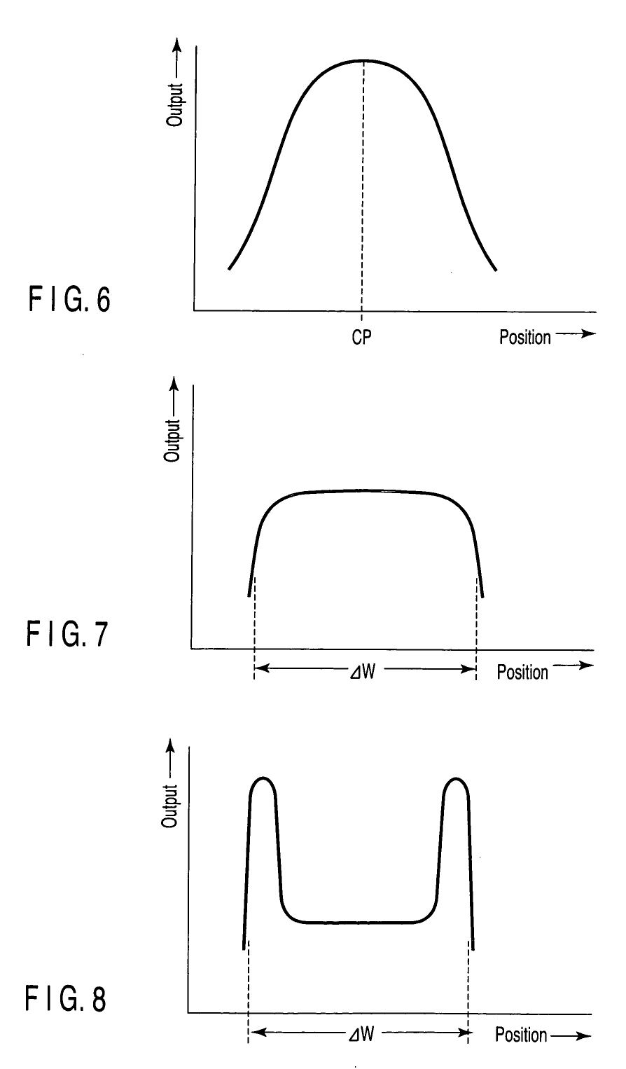

FIG. 6 is a characteristic diagram showing the relationship between the laser irradiation position and the output. As shown in FIG. 6, the laser output normally has a characteristic with the peak in its center position CP. In contrast, in the first and third embodiments, the peeling of the multilayer film 15 can be prevented more effectively by irradiating laser which has a flat characteristic as shown in FIG. 7 all over the laser scanning width ΔW or a characteristic with peaks at both ends of the scanning width ΔW as shown in FIG. 8.

The characteristics as shown in FIGS. 7 and 8 can be realized by adjusting the optical system of the laser irradiation unit.

As described above, according to one aspect of this invention, a semiconductor device manufacturing method capable of preventing chipping and the peeling of a low-relative-permittivity insulating film can be provided.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A semiconductor device manufacturing method comprising:
forming semiconductor elements in a semiconductor wafer;
forming a multilayer film including a low-relative-permittivity insulating film, at the upper layer of the semiconductor wafer;
forming a metal layer functioning as at least an alignment mark and a test pad, on a dicing line of the multilayer film;
irradiating laser onto a region covering the alignment mark and test pad on the dicing line; and
performing mechanical dicing on at least one of the alignment mark and test pad on the dicing line in such a manner that the dicing is narrower in width than the laser-irradiated region, thereby segmenting the semiconductor wafer to form semiconductor chips.

2. The semiconductor device manufacturing method according to claim 1, further comprising forming a laser absorbing member layer on the multilayer film excluding the alignment mark and test pad on the laser-irradiated region after forming the metal layer and before irradiating the laser.

3. The semiconductor device manufacturing method according to claim 1, wherein the irradiating laser is to irradiate laser as far as a depth at which at least the multilayer film is removed or changes its nature.

4. The semiconductor device manufacturing method according to claim 1, wherein the irradiating laser is to irradiate laser as far as a depth at which the multilayer film is severed with laser and a part of the surface of the wafer is melted.

5. The semiconductor device manufacturing method according to claim 1, wherein the irradiating laser is to irradiate laser onto a region at least 3 μm wider than either end of each of the alignment mark and test pad.

6. The semiconductor device manufacturing method according to claim 1, wherein the mechanical dicing is blade dicing.

7. The semiconductor device manufacturing method according to claim 1, wherein the irradiating laser is to irradiate a first and a second laser beam in parallel as far as a depth at which at least the multilayer film is removed or changes its nature, and
the performing mechanical dicing is to perform blade dicing on the region between the regions onto which the first and second laser beams have been irradiated.

8. The semiconductor device manufacturing method according to claim 1, wherein the frequency of the laser is in the range of 50 KHz to 200 KHz.

9. The semiconductor device manufacturing method according to claim 1, wherein the wavelength of the laser is in the range of 266 nm to 1064 nm.

10. The semiconductor device manufacturing method according to claim 1, wherein the output of the laser is in the range of 0.5 W to 4.5 W.

11. The semiconductor device manufacturing method according to claim 1, wherein the moving speed of the laser irradiation position is in the range of 10 mm/sec to 300 mm/sec.

12. The semiconductor device manufacturing method according to claim 1, wherein the laser includes pulses whose width is in the range of 10 nsec to 300 nsec.

13. The semiconductor device manufacturing method according to claim 1, wherein the laser has a flat characteristic all over the scanning width.

14. The semiconductor device manufacturing method according to claim 1, wherein the laser has a characteristic with peaks at both ends of the scanning width.
